(19) United States
(12) Patent Application Publication
(10) Pub. No.: US 2015/0118622 A1
(43) Pub. Date: Apr. 30, 2015

(54) Positive Photosensitive Resin Composition, Photosensitive Resin Film Prepared by Using the Same, and Display Device

(71) Applicant: Cheil Industries Inc., Gumi-si (KR)

(72) Inventors: Jin-Hee KANG, Uiwang-si (KR); Ji-Yun KWON, Uiwang-si (KR); Dae-Yun KIM, Uiwang-si (KR); Sang-Kyeon KIM, Uiwang-si (KR); Sang-Soo KIM, Uiwang-si (KR); Yong-Tae KIM, Uiwang-si (KR); Kun-Bae NOH, Uiwang-si (KR); Eun-Bi PARK, Uiwang-si (KR); Jae-Yeol BAEK, Uiwang-si (KR); Jae-Hwan SONG, Uiwang-si (KR); Bum-Jin LEE, Uiwang-si (KR); Jong-Hwa LEE, Uiwang-si (KR); Jin-Young LEE, Uiwang-si (KR); Chung-Beum HONG, Uiwang-si (KR); Eun-Ha HWANG, Uiwang-si (KR); In-Chul HWANG, Uiwang-si (KR)

(73) Assignee: Cheil Industries Inc., Gumi-si (KR)

(21) Appl. No.: 14/284,887

(22) Filed: May 22, 2014

(30) Foreign Application Priority Data
Oct. 30, 2013 (KR) 10-2013-0130245

(51) Int. Cl. G03F 7/039

(52) U.S. Cl. CPC G03F 7/039
USPC 430/286.1

(57) ABSTRACT

Disclosed are a positive photosensitive resin composition including (A) a polybenzoxazole precursor having a polydispersity of about 1 to about 1.6; (B) a photosensitive diazoquinone compound; (C) a thermal acid generator; and (D) a solvent, a photosensitive resin film using the same, and a display device.

### CROSS-REFERENCE TO RELATED APPLICATION

This application claims priority to and the benefit of Korean Patent Application No. 10-2013-0130245 filed in the Korean Intellectual Property Office on Oct. 30, 2013, the entire disclosure of which is incorporated herein by reference.

### FIELD OF THE INVENTION

This disclosure relates to a positive photosensitive resin composition, a photosensitive resin film prepared by using the same, and a display device including the photosensitive resin film.

### BACKGROUND

Aromatic polyimide (PI) and aromatic polybenzoxazole (PBO) are representative polymers having a rigid aromatic backbone. Such polymers can have excellent mechanical strength, chemical resistance, weather resistance, heat resistance, and shape stability based on chemical stability of rings and excellent electrical characteristics such as insulation characteristics and the like due to a low dielectric constant. Thus, these polymers are actively used as an electric/electronic material and also have received attention as a material for automotive and aerospace applications.

For example, positive photosensitive resin compositions including a polybenzoxazole precursor are increasingly used as a material for an organic insulation layer or a barrier rib in a display field. Positive photosensitive resin compositions including a polybenzoxazole precursor also are increasingly used for laptop computers, monitors, and TV screens due to lightness and thinness of a display, a low price, low power consumption for operation, and excellent adherence to an integrated circuit.

However, polybenzoxazole precursors in the positive photosensitive resin composition have a non-uniform molecular weight due to a low molecular component in the precursor. Accordingly, the composition in an exposure region does not absorb energy uniformly during exposure and generates a development residue (scum), which can decrease resolution and sensitivity. In addition, the polybenzoxazole precursor having a non-uniform molecular weight may cause out-gassing.

### SUMMARY

One embodiment of the present invention provides a positive photosensitive resin composition that can have improved resolution, sensitivity, and/or a film residue ratio by controlling polydispersity of polybenzoxazole.

Another embodiment of the present invention provides a photosensitive resin film using the positive photosensitive resin composition.

Yet another embodiment of the present invention provides a display device including the photosensitive resin film.

One embodiment of the present invention provides a positive photosensitive resin composition that includes (A) a polybenzoxazole precursor having a polydispersity of about 1 to about 1.6; (B) a photosensitive diazoquinone compound; (C) a thermal acid generator; and (D) a solvent.

A weight average molecular weight (Mw) of the polybenzoxazole precursor may be about 3,000 g/mol to about 30,000 g/mol.

The polybenzoxazole precursor may include a repeating unit represented by the following Chemical Formula 1.

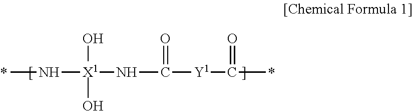

In the above Chemical Formula 1,

each X¹ is the same or different and each is independently a substituted or unsubstituted C6 to C30 aromatic organic group, and

each Y¹ is the same or different and each is independently a substituted or unsubstituted C6 to C30 aromatic organic group, a substituted or unsubstituted divalent to hexavalent C1 to C30 aliphatic organic group, or a substituted or unsubstituted divalent to hexavalent C3 to C30 alicyclic organic group.

The positive photosensitive resin composition may include about 5 parts by weight to about 100 parts by weight of the photosensitive diazoquinone compound (B); about 1 part by weight to about 50 parts by weight of the thermal acid generator (C); and about 100 parts by weight to about 400 parts by weight of the solvent (D), each based on about 100 parts by weight of the polybenzoxazole precursor (A).

The positive photosensitive resin composition may further include an additive such as a silane compound, a surfactant, a leveling agent, and/or a combination thereof.

Another embodiment of the present invention provides a photosensitive resin film prepared using the positive photosensitive resin composition.

Yet another embodiment of the present invention provides a display device including the photosensitive resin film.

The positive photosensitive resin composition according to one embodiment of the present invention may provide a photosensitive resin film having excellent resolution, sensitivity, and/or a film residue ratio and a display device including the photosensitive resin film.

### DETAILED DESCRIPTION

The present invention now will be described more fully hereinafter in the following detailed description of the invention, in which some, but not all embodiments of the invention are described. Indeed, this invention may be embodied in many different forms and should not be construed as limited to the embodiments set forth herein; rather, these embodiments are provided so that this disclosure will satisfy applicable legal requirements.

As used herein, when a specific definition is not otherwise provided, the term “substituted” refers to one substituted with at least one substituent including halogen (F, Br, Cl or I), a hydroxy group, a nitro group, a cyano group, an amino group (NH₂, NH(R²⁰⁰) or N(R²⁰¹)(R²⁰²), wherein R²⁰⁰, R²⁰¹ and R²⁰² are the same or different, and are independently C1 to C10 alkyl), an amidino group, a hydrazine group, a hydrazone group, a carboxyl group, substituted or unsubstituted alkyl, substituted or unsubstituted alkenyl, substituted or unsubstituted alkynyl, substituted or unsubstituted alkoxy, a substituted or unsubstituted alicyclic organic group, substituted or unsubstituted aryl, a substituted or unsubstituted heterocyclic group, or a combination thereof, in place of at least one hydrogen of a functional group.

As used herein, when a specific definition is not otherwise provided, the term “alkyl” refers to C1 to C20 alkyl, for example C1 to C15 alkyl, the term “cycloalkyl” refers to C3 to C20 cycloalkyl, for example C3 to C18 cycloalkyl, the term “alkoxy” refers to C1 to C20 alkoxy, for example C1 to C18 alkoxy, the term “aryl” refers to C6 to C20 aryl, for example C6 to C18 aryl, the term “alkenyl” refers to C2 to C20 alkenyl, for example C2 to C18 alkenyl, the term “alkylene” refers to C1 to C20 alkylene, for example C1 to C18 alkylene, and the term “arylene” refers to C6 to C20 arylene, for example C6 to C16 arylene.

As used herein, when a specific definition is not otherwise provided, the term “aliphatic organic group” refers to C1 to C20 alkyl, C2 to C20 alkenyl, C2 to C20 alkynyl, C1 to C20 alkylene, C2 to C20 alkenylene, or C2 to C20 alkynylene, for example C1 to C15 alkyl, C2 to C15 alkenyl, C2 to C15 alkynyl, C1 to C15 alkylene, C2 to C15 alkenylene, or C2 to C15 alkynylene, the term “alicyclic organic group” refers to C3 to C20 cycloalkyl, C3 to C20 cycloalkenyl, C3 to C20 cycloalkynyl, C3 to C20 cycloalkylene, C3 to C20 cycloalkenylene, or C3 to C20 cycloalkynylene, for example C3 to C15 cycloalkyl, C3 to C15 cycloalkenyl, C3 to C15 cycloalkynyl, C3 to C15 cycloalkylene, C3 to C15 cycloalkenylene, or C3 to C15 cycloalkynylene, the term “aromatic organic group” refers to C6 to C20 aryl or C6 to C20 arylene, for example C6 to C16 aryl or C6 to C16 arylene, the term “heterocyclic group” refers to C2 to C20 cycloalkyl, C2 to C20 cycloalkylene, C2 to C20 cycloalkenyl, C2 to C20 cycloalkenylene, C2 to C20 cycloalkynyl, C2 to C20 cycloalkynylene, C2 to C20 heteroaryl, or C2 to C20 heteroarylene that includes 1 to 3 hetero atoms including O, S, N, P, Si, or a combination thereof in a ring, for example C2 to C15 cycloalkyl, C2 to C15 cycloalkylene, C2 to C15 cycloalkenyl, C2 to C15 cycloalkenylene, C2 to C15 cycloalkynyl, C2 to C15 cycloalkynylene, C2 to C15 heteroaryl, or C2 to C15 heteroarylene that includes 1 to 3 hetero atoms including O, S, N, P, Si, or a combination thereof in a ring.

As used herein, when a definition is not otherwise provided, the term “combination” refers to mixing or copolymerization. In addition, the term “copolymerization” refers to block copolymerization and/or random copolymerization, and the term “copolymer” refers to a block copolymer and/or a random copolymer.

As used herein, unless a specific definition is otherwise provided, a hydrogen atom is bonded at a position when a chemical bond is not drawn where a bond would otherwise appear.

Also, “*” refers to a linking part between the same or different atoms, or Chemical Formulae.

A positive photosensitive resin composition according to one embodiment of the present invention includes (A) a polybenzoxazole precursor having a polydispersity of about 1 to about 1.6; (B) a photosensitive diazoquinone compound; (C) a thermal acid generator; and (D) a solvent.

In general, a synthesized polybenzoxazole precursor includes a low molecular weight component and thus, has a wide molecular weight distribution due to the low molecular weight component. The positive photosensitive resin composition including the polybenzoxazole precursor having a wide molecular weight distribution may not uniformly absorb energy in an exposure region during exposure and can generate a development residue (a scum).

The low molecular weight component may be a monomer, a dimer, a trimer, and the like having relatively high polarity and a weight average molecular weight of less than or equal to about 500 g/mol but is not limited thereto.

Accordingly, one embodiment of the present invention provides a polybenzoxazole precursor obtained by purifying a synthesized polybenzoxazole precursor with water and a polar organic solvent to remove the low molecular weight component. The polybenzoxazole precursor has polydispersity of about 1 to about 1.6 and generates minimal or no development residue (scum) since the low molecular component is removed therefrom and thus, may improve resolution, sensitivity, and/or a film residue ratio of a composition.

Hereinafter, each component of the positive photosensitive resin composition is described in detail.

(A) Polybenzoxazole Precursor

The positive photosensitive resin composition according to one embodiment includes a polybenzoxazole precursor having a polydispersity of about 1 to about 1.6.

When the polybenzoxazole precursor has polydispersity of greater than about 1.6, the polybenzoxazole precursor may include a plurality of low molecular regions and may generate a development residue (scum). This can deteriorate resolution, sensitivity, and a film residue ratio

The polydispersity indicates a value (Mw/Mn) obtained by dividing a weight average molecular weight (Mw) by a number average molecular weight (Mn).

A polybenzoxazole precursor having a polydispersity within the above range may be obtained by removing a low molecular component therein through purification with water and a polar organic solvent.

Examples of the polar organic solvent may include, for example, acetic acid, isopropylalcohol, methanol, acetone, tetrahydrofuran, and the like, and combinations thereof. In addition, the polar organic solvent may be mixed with water such as ultrapure water and the like in a predetermined ratio (e.g., in a ratio of about 6:4 to about 9:1 between the water and the polar solvent).

A positive photosensitive resin composition including the polybenzoxazole precursor obtained after removing the low molecular component may form a uniform pattern having minimal or no development residue (scum) and may remove out-gassing during development.

The polybenzoxazole precursor may have a weight average molecular weight (Mw) of about 3,000 g/mol to about 30,000 g/mol, for example about 5,000 g/mol to about 15,000 g/mol.

When the polybenzoxazole precursor has a weight average molecular weight (Mw) within the above range, a sufficient film residue ratio in a non-exposed region may be obtained during development, and patterning may be efficiently performed.

The polybenzoxazole precursor may include a repeating unit represented by the following Chemical Formula 1.

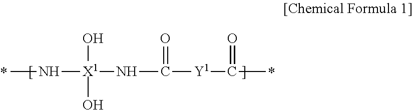

In the above Chemical Formula 1,

each X¹ is the same or different and each is independently a substituted or unsubstituted C6 to C30 aromatic organic group, and

each Y¹ is the same or different and each is independently a substituted or unsubstituted C6 to C30 aromatic organic group, a substituted or unsubstituted divalent to hexavalent C1 to C30 aliphatic organic group, or a substituted or unsubstituted divalent to hexavalent C3 to C30 alicyclic organic group.

In the above Chemical Formula 1, X′ may be an aromatic organic group which is a residual group derived from aromatic diamine.

Examples of the aromatic diamine may include without limitation 3,3′-diamino-4,4′-dihydroxybiphenyl, 4,4′-diamino-3,3′-dihydroxybiphenyl, bis(3-amino-4-hydroxyphenyl)propane, bis(4-amino-3-hydroxyphenyl)propane, bis(3-amino-4-hydroxyphenyl)sulfone, bis(4-amino-3-hydroxyphenyl)sulfone, 2,2-bis(3-amino-4-hydroxyphenyl)-1,1,1,3,3,3-hexafluoropropane, 2,2-bis(4-amino-3-hydroxyphenyl)-1,1,1,3,3,3-hexafluoropropane, 2,2-bis(3-amino-4-hydroxy-5-trifluoromethylphenyl)hexafluoropropane, 2,2-bis(3-amino-4-hydroxy-6-trifluoromethylphenyl)hexafluoropropane, 2,2-bis(3-amino-4-hydroxy-2-trifluoromethylphenyl)hexafluoropropane, 2,2-bis(4-amino-3-hydroxy-5-trifluoromethylphenyl)hexafluoropropane, 2,2-bis(4-amino-3-hydroxy-6-trifluoromethylphenyl)hexafluoropropane, 2,2-bis(4-amino-3-hydroxy-2-trifluoromethylphenyl)hexafluoropropane, 2,2-bis(3-amino-4-hydroxy-5-pentafluoroethylphenyl)hexafluoropropane, 2-(3-amino-4-hydroxy-5-trifluoromethylphenyl)-2-(3-amino-4-hydroxy-5-pentafluoroethylphenyl)hexafluoropropane, 2-(3-amino-4-hydroxy-5-trifluoromethylphenyl)-2-(3-hydroxy-4-amino-5-trifluoromethylphenyl)hexafluoropropane, 2-(3-amino-4-hydroxy-5-trifluoromethylphenyl)-2-(3-hydroxy-4-amino-6-trifluoromethylphenyl)hexafluoropropane, 2-(3-amino-4-hydroxy-5-trifluoromethylphenyl)-2-(3-hydroxy-4-amino-2-trifluoromethylphenyl)hexafluoropropane, 2-(3-amino-4-hydroxy-2-trifluoromethylphenyl)-2-(3-hydroxy-4-amino-5-trifluoromethylphenyl)hexafluoropropane, 2-(3-amino-4-hydroxy-6-trifluoromethylphenyl)-2-(3-hydroxy-4-amino-5-trifluoromethylphenyl)hexafluoropropane, and the like, and combinations thereof.

Examples of the X¹ may include one or more functional groups represented by the following Chemical Formulae 20 and 21, but are not limited thereto.

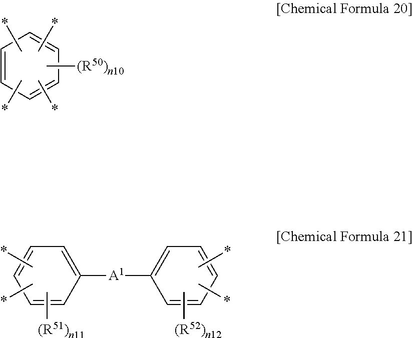

In the above Chemical Formulae 20 and 21,

A¹ is a single bond, O, CO, CR⁴⁷R⁴⁸, SO₂, or S, wherein R⁴⁷ and R⁴⁸ are the same or different and are each independently hydrogen or substituted or unsubstituted C1 to C30 alkyl, for example C1 to C30 fluoroalkyl,

R⁵⁰ to R⁵² are the same or different and are each independently hydrogen, substituted or unsubstituted C1 to C30 alkyl, a substituted or unsubstituted C1 to C30 carboxyl group, a hydroxy group or thiol group, and n10 is an integer of 0 to 2, and n11 and n12 are the same or different and are each independently integers of 0 to 3.

In the above Chemical Formula 1, Y¹ is an aromatic organic group, a divalent to hexavalent aliphatic organic group, or a divalent to hexavalent alicyclic organic group, and may be a residual group of dicarboxylic acid or a residual group of a dicarboxylic acid derivative. In exemplary embodiments, Y¹ may be an aromatic organic group or a divalent to hexavalent alicyclic organic group.

Examples of the dicarboxylic acid derivative may include without limitation 4,4′-oxydibenzoyl chloride, diphenyloxydicarbonyldichloride, bis(phenylcarbonyl chloride)sulfone, bis(phenylcarbonyl chloride)ether, bis(phenylcarbonyl chloride)phenone, phthaloyldichloride, terephthaloyldichloride, isophthaloyldichloride, dicarbonyldichloride, diphenyloxydicarboxylatedibenzotriazole, and the like, and combinations thereof.

Examples of Y¹ may include one or more functional groups represented by the following Chemical Formulae 22 to 24, but are not limited thereto.

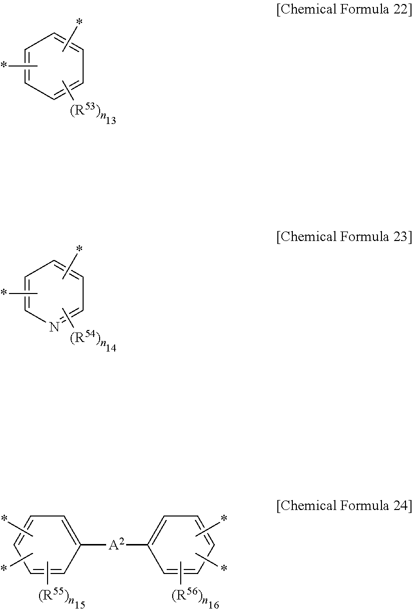

In the above Chemical Formulae 22 to 24,

R⁵³ to R⁵⁶ are the same or different and are each independently hydrogen or substituted or unsubstituted C1 to C30 alkyl,

n13 and n14 are the same or different and are each independently integers of 0 to 4,

n15 and n16 are the same or different and are each independently integers of 0 to 3, and

A² is a single bond, O, CR⁴⁷R⁴⁸, CO, CONH, S, or SO₂, wherein R⁴⁷ and R⁴⁸ are the same or different and are each independently hydrogen or substituted or unsubstituted C1 to C30 alkyl, for example C1 to C30 fluoroalkyl.

The polybenzoxazole precursor may have a thermally polymerizable functional group derived from a reactive end-capping monomer at one terminal end or both terminal ends. Examples of the reactive end-capping monomer may include without limitation monoamines, monoanhydrides, and the like, and combinations thereof having a carbon-carbon double bond. Examples of the monoamines may include without limitation toluidine, dimethylaniline, ethylaniline, aminophenol, aminobenzylalcohol, aminoindan, aminoacetonephenone, and the like, and combinations thereof.

(B) Photosensitive Diazoquinone Compound

The photosensitive diazoquinone compound may be a compound having a 1,2-benzoquinone diazide structure and/or a 1,2-naphthoquinone diazide structure.

Examples of the photosensitive diazoquinone compound may include at least one selected from the compounds represented by the following Chemical Formulae 10 and 12 to 14, but are not limited thereto.

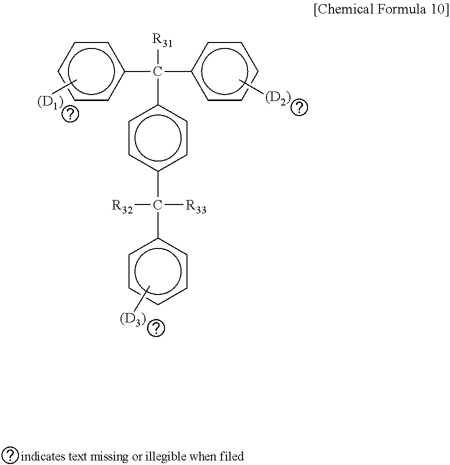

In the above Chemical Formula 10,

R₃₁ to R₃₃ are the same or different and are each independently hydrogen or substituted or unsubstituted alkyl, for example CH₃,

D₁ to D₃ are the same or different and are each independently OQ, wherein Q is hydrogen or the following Chemical Formula 11a or 11b, provided that Qs are not simultaneously hydrogen, and

n31 to n33 are the same or different and are each independently integers ranging from 1 to 3.

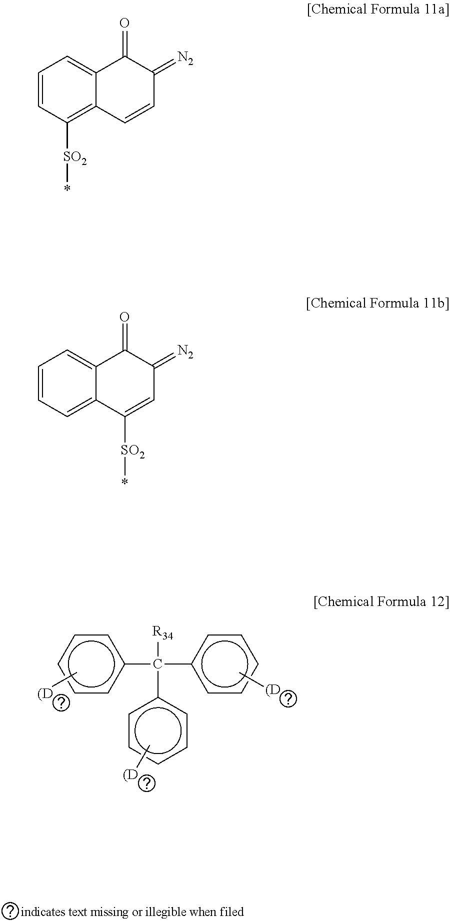

In the above Chemical Formula 12,

R₃₄ is hydrogen or substituted or unsubstituted alkyl, for example, CH₃,

D₄ to D₆ are the same or different and are each independently OQ, wherein Q is the same as defined in the above Chemical Formula 10, and

n34 to n36 are the same or different and are each independently integers ranging from 1 to 3.

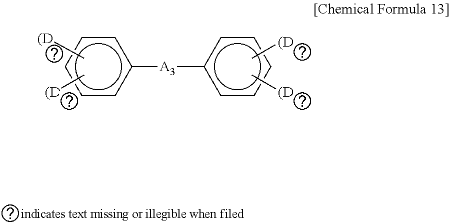

In the above Chemical Formula 13,

A₃ is CO or CRR′, wherein R and R′ are the same or different and are each independently substituted or unsubstituted alkyl, for example, CH₃,

D₇ to D₁₀ are the same or different and are each independently, hydrogen, substituted or unsubstituted alkyl, OQ, or NHQ, wherein Q is the same as defined in the above Chemical Formula 10,

n37, n38, n39 and n40 are the same or different and are each independently integers ranging from 1 to 4,

n37+n38 and n39+n40 are the same or different and are each independently integers of less than or equal to 5,

at least one of the D₇ to D₁₀ is OQ, and one aromatic ring includes one to three OQs and the other aromatic ring includes one to four OQs.

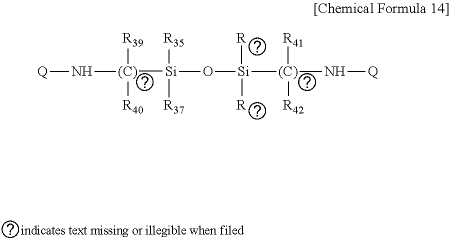

In the above Chemical Formula 14,

R₃₅ to R₄₂ are the same or different and are each independently, hydrogen or substituted or unsubstituted alkyl,

n41 and n42 are the same or different and are each independently integers ranging from 1 to 5, for example 2 to 4, and

Q is the same as defined in the above Chemical Formula 10.

The positive photosensitive resin composition may include the photosensitive diazoquinone compound in an amount of about 5 to about 100 parts by weight based on about 100 parts by weight of the polybenzoxazole precursor. In some embodiments, the positive photosensitive resin composition may include the photosensitive diazoquinone compound in an amount of about 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, or 100 parts by weight. Further, according to some embodiments of the present invention, the amount of the photosensitive diazoquinone compound can be in a range from about any of the foregoing amounts to about any other of the foregoing amounts.

When the photosensitive diazoquinone compound is included in an amount within the above range, the pattern can be well-formed with minimal or no residue from exposure, and a film thickness loss during development may be prevented and thereby a good pattern can be provided.

(C) Thermal Acid Generator

A thermal acid generator used in the present invention is thermally decomposed and generates acid and may include a conventional thermal acid generator. The thermal acid generator may have a thermal decomposition temperature in a range of about 120° C. to about 200° C.

A thermal acid generator having a thermal decomposition temperature within the above range may have an effect of decreasing out-gas and/or realizing excellent reliability.

The thermal acid generator of the present invention may be, for example, a compound represented by the following Chemical Formula 2, Chemical Formula 3, or a combination thereof.

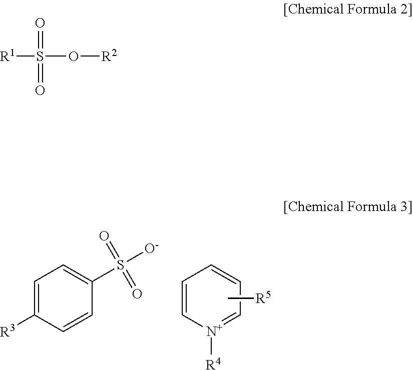

In the above Chemical Formulae 2 and 3, R¹ to R⁵ are the same or different and are each independently hydrogen, halogen, a hydroxy group, substituted or unsubstituted C1 to C30 alkyl, substituted or unsubstituted C2 to C30 alkenyl, substituted or unsubstituted C1 to C30 alkynyl, substituted or unsubstituted C1 to C30 alkoxy, substituted or unsubstituted C6 to C30 aryl, substituted or unsubstituted C3 to C30 cycloalkyl, or a combination thereof.

The compounds of the above Chemical Formula 2 may include at least one or more compounds represented by the following Chemical Formulae 2a to 2c.

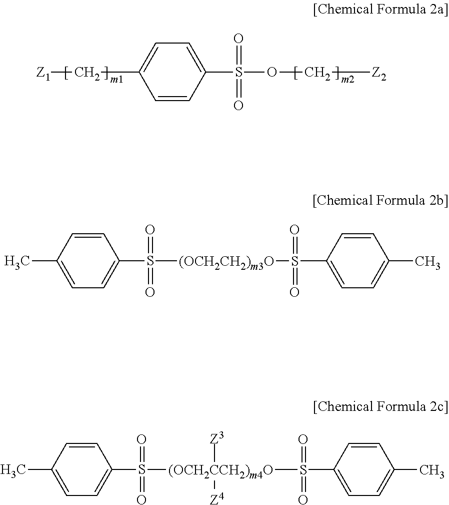

In the above Chemical Formulae 2a to 2c:

m1 to m4 are the same or different and are each independently integers ranging from 0 to 10, for example 0 to 6, and

Z₁, Z₂, Z³ and Z⁴ are the same or different and are each independently hydrogen, halogen, a hydroxy group, substituted or unsubstituted C1 to C30 alkyl, substituted or unsubstituted C2 to C30 alkenyl, substituted or unsubstituted C1 to C30 alkynyl, substituted or unsubstituted C1 to C30 alkoxy, substituted or unsubstituted C6 to C30 aryl, or a combination thereof.

The compounds of the above Chemical Formula 2 may include at least one or more compounds represented by one of the following Chemical Formulae 29 to 33, and the compounds of the above Chemical Formula 3 may include at least one or more compounds represented by the following Chemical Formula 34 or Chemical Formula 35.

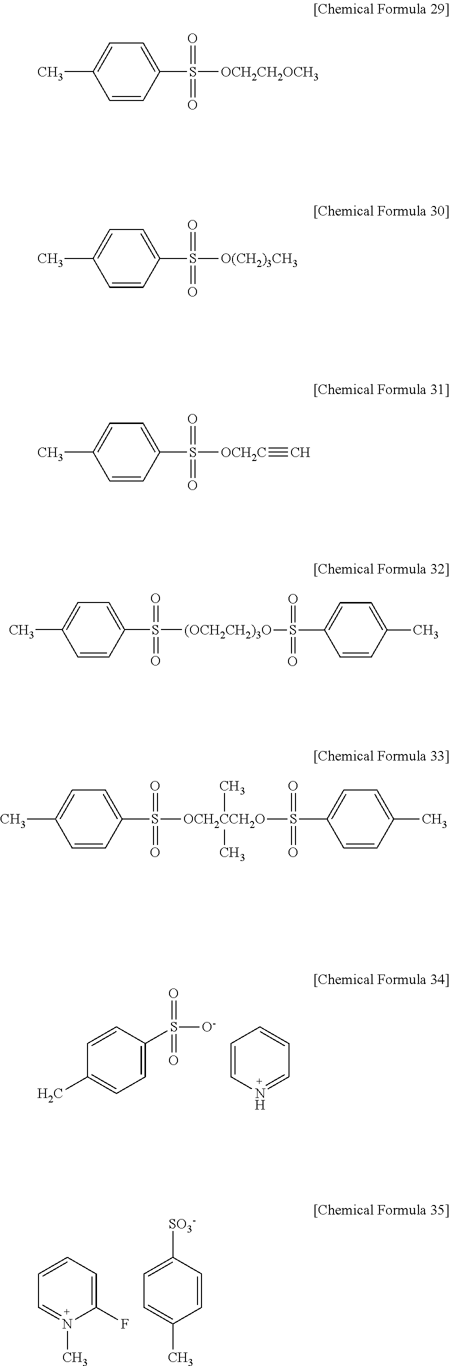

The positive photosensitive resin composition may include the thermal acid generator in an amount of about 1 part by weight to about 50 parts by weight, for example, about 3 parts by weight to about 30 parts by weight, based on about 100 parts by weight of the polybenzoxazole precursor. In some embodiments, the positive photosensitive resin composition may include the thermal acid generator in an amount of about 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 parts by weight. Further, according to some embodiments of the present invention, the amount of the thermal acid generator can be in a range from about any of the foregoing amounts to about any other of the foregoing amounts.

When the thermal acid generator is used in an amount within the above range, an insulation layer formed of the composition may have excellent thermal and mechanical characteristics due to sufficient ring closure of the polybenzoxazole precursor, and the composition may also have excellent storage stability.

The thermal acid generator may be selected depending on a curing temperature condition and used alone or as a mixture of more than two.

(D) Solvent

The positive photosensitive resin composition may include a solvent that is capable of easily dissolving each component. The solvent can improve uniformity of a layer during coating and can prevent a coating stain and/or a pin spot and thus can promote formation of a uniform pattern.

Examples of the solvent mayinclude without limitation alcohols such as methanol, ethanol, benzylalcohol, hexylalcohol, and the like; ethylene glycolalkyletheracetates such as ethylene glycolmethyletheracetate, ethylene glycol ethyletheracetate, and the like; ethylene glycol alkyl ether propionates such as ethylene glycolmethyletherpropionate, ethylene glycolethyletherpropionate, and the like; ethylene glycolmonoalkylethers such as ethylene glycolmethylether, ethylene glycolethylether, and the like; diethylene glycolalkylethers such as diethylene glycolmonomethylether, diethylene glycol monoethylether, diethylene glycol dimethylether, diethylene glycolmethylethylether, and the like; propylene glycolalkyletheracetates such as propylene glycol methylether acetate, propylene glycolethyletheracetate, propylene glycolpropyletheracetate and the like; propylene glycolalkyletherpropionates such as propylene glycolmethyletherpropionate, propylene glycolethyletherpropionate, propylene glycolpropyletherpropionate, and the like; propylene glycolmonoalkylethers such as propylene glycolmethylether, propylene glycolethylether, propylene glycolpropylether, propylene glycolbutylether, and the like; dipropylene glycolalkylethers such as dipropylene glycoldimethylether, dipropylene glycoldiethylether and the like; butylene glycolmonomethylethers such as butylene glycolmonomethylether, butylene glycolmonoethylether, and the like; dibutylene glycolalkylethers such as dibutylene glycoldimethylether, dibutylene glycoldiethylether, and the like, and the like. The solvent may be used singularly or as a mixture of two or more.

In exemplary embodiments, examples of the solvent may include without limitation N-methyl-2-pyrrolidone, γ-butyrolactone, N,N-dimethylacetamide, dimethylsulfoxide, diethylene glycoldimethylether, diethylene glycoldiethylether, diethylene glycoldibutylether, propylene glycolmonomethylether, dipropylene glycolmonomethylether, propylene glycolmonomethyl ether acetate, methyl lactate, ethyl lactate, butyl lactate, methyl-1,3-butylene glycolacetate, 1,3-butylene glycol-3-monomethylether, methyl pyruvate, ethyl pyruvate, methyl-3-methoxy propionate, and the like, and these may be used as a mixture of two or more kinds.

The solvent may be selected appropriately depending on a process of forming a photosensitive resin film such as spin coating, slit die coating, and the like.

The positive photosensitive resin composition may include the solvent in an amount of about 100 parts by weight to about 400 parts by weight based on about 100 parts by weight of the polybenzoxazole precursor. Within this range, a sufficiently thick film may be obtained, and good solubility and coating properties may be provided.

(E) Other Additive(s)

The positive photosensitive resin composition according to one embodiment may further include one or more other additives. Examples of the additives may include without limitation silane compounds, surfactants, leveling agents, and the like, and combinations thereof.

For the other additives, a suitable surfactant and/or leveling agent may be included in order to prevent a stain of the film and/or to improve the development. In addition, a silane coupling agent may be used as an adherence enhancer to increase adherence to a substrate.

The surfactant may include a siloxane-based surfactant and/or a surfactant having a fluorine atom and may be used in an amount of about 0.005 parts by weight to about 0.3 parts by weight based on the total amount (total weight, 100 wt %) of the photosensitive resin composition.

The siloxane-based surfactant can suppress a defect such as a stain and the like on a coating layer formed of the photosensitive resin composition, and can highly improve coating characteristics. The surfactant having a fluorine atom can largely suppress generation of a pin spot and a Bernard cell on the coating layer.

The silane compound may be represented by the following Chemical Formula 6 and/or Chemical Formula 7.

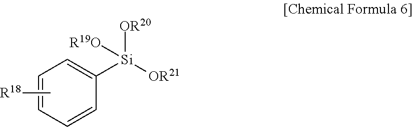

In the above Chemical Formula 6,

R¹⁸ is NH₃ or CH₃CONH, and

R¹⁹ to R²¹ are the same or different and are each independently CH₃ or CH₂CH₃.

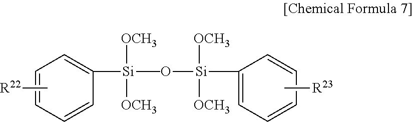

In the above Chemical Formula 7,

R²² and R²³ are the same or different and are each independently NH₃ or CH₃CONH.

In exemplary embodiments of the present invention, the silane compound may be a carbon-carbon unsaturated bond-containing silane compound. Examples of silane compounds may include without limitation vinyltrimethoxysilane, vinyltriethoxysilane, vinyl trichlorosilane, vinyltris(β-methoxyethoxy)silane; 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane; trimethoxy[3-(phenylamino)propyl]silane, and the like, and combinations thereof.

The silane compound may be used in an amount of about 0.1 parts by weight to about 30 parts by weight based on about 100 parts by weight of the polybenzoxazole precursor.

When the positive photosensitive resin composition according to the embodiment is used to form a pattern, a process of forming the pattern can include coating the positive photosensitive resin composition on a supportive substrate using spin coating, slit coating, inkjet printing, and the like; drying the coated positive photosensitive resin composition to form a positive photosensitive resin composition layer; exposing the positive photosensitive resin composition layer; developing the exposed positive photosensitive resin composition layer in an alkali aqueous solution to manufacture a photosensitive resin film; and heat-treating the photosensitive resin film. The patterning process is performed under conditions well-known in the art, and the conditions will not be illustrated in detail here.

According to one embodiment, a photosensitive resin film prepared using the positive photosensitive resin composition is provided.

The photosensitive resin film may be, for example an organic insulation layer, a buffer layer, or a protective layer.

According to yet another embodiment of the present invention, a display device including the photosensitive resin film is provided.

The display device may be an organic light emitting diode (OLED) or a liquid crystal display (LCD).

In other words, the positive photosensitive resin composition according to one embodiment of the present invention may be usefully applied to form an organic insulation layer, a planarization layer, a passivation layer, and/or an interlayer insulation layer in a display device.

Hereinafter, the present invention is illustrated in more detail with reference to the following examples and comparative examples. However, the following examples and comparative examples are provided for the purpose of illustration only and the present invention is not limited thereto.

### EXAMPLE

### Synthesis of Unpurified Polybenzoxazole Precursor

### Synthesis Example 1

820 g of N-methyl pyrrolidone is added to a 4-necked flask having an agitator, a temperature controller, a nitrogen gas injector, and a cooler, while nitrogen is passed therethrough, 80.84 g of 2,2′-bis(3-amino-4-hydroxyphenyl)hexafluoropropane, 14.32 g of 5-norbornene-2,3-dicarboxyl anhydride, and 31.43 g of pyridine are added thereto and dissolved therein by agitating the mixture. While the temperature is maintained at 0° C. to 10° C., 53.42 g of dioxybenzoyl chloride is slowly added thereto in a dropwise fashion for 30 minutes, and the mixture is agitated for 180 minutes, completing the reaction. Weight average molecular weight (Mw) of the synthesized polybenzoxazole precursor (polyhydroxyamide-1: PHA-1) is 7,000, and polydispersity of the precursor is 1.72.

### Synthesis Example 2

800.83 g of N-methyl pyrrolidone is added to a 4-necked flask having an agitator, a temperature controller, a nitrogen gas injector, and a cooler, while nitrogen is passed therethrough, 97.95 g of 2,2′-bis(3-amino-4-hydroxyphenyl)hexafluoropropane, and 14.39 g of benzene-1,2,4-tricarboxylic anhydride, and 40.02 g of pyridine are added thereto and dissolved therein by agitating the mixture. While the temperature is maintained at 0° C. to 10° C., 63.87 g of dioxybenzoyl chloride is slowly added thereto in a dropwise fashion for 30 minutes, and the mixture is agitated for 180 minutes, completing the reaction. Weight average molecular weight (Mw) of the synthesized polybenzoxazole precursor (polyhydroxyamide-2: PHA-2) is 8,500, and polydispersity of the precursor is 1.81.

### Synthesis of Purified Polybenzoxazole Precursor and Photosensitive Resin Composition

### Examples 1 to 11 and Comparative Examples 1 to 10

900 g of the polybenzoxazole precursor (PHA-1) according to Synthesis Example 1 is added in a dropwise fashion at a flow rate of 80 mL/s to 5,000 mL of a solution obtained by mixing ultrapure water and a polar solvent (tetrahydrofuran (THF), acetic acid, acetone, methanol, and isopropyl alcohol (IPA)) in a ratio provided in the following Table 1 at room temperature to produce a precipitate, and the mixture is agitated for 30 minutes. The obtained slurry including the precipitate is filtered with a glass filter having a pore size of 1 μm. The filtered white powder is dissolved in 900 g of propylene glycolmonomethylether. Then, 900 g of the solution is added in a dropwise fashion in 5 L of a solution obtained by mixing ultrapure water:methanol in a volume ratio of 60:40 at a flow rate of 80 mL/s to produce a precipitate, and the mixture is agitated for 30 minutes. After repeating this process three times in total, the reactant is dried at 80° C. under vacuum for greater than or equal to 24 hours to remove a low molecular weight component, obtaining a polybenzoxazole precursor (PHA-D1).

15 g of the polybenzoxazole precursor (PHA-D1), 5.31 g of photosensitive diazoquinone having a structure represented by the following Chemical Formula 36, 0.75 g of a thermal acid generator having the following Chemical Formula 29, 33.355 g of propylene glycol monomethylether, 15.395 g of ethyl lactate, 2.566 g of γ-butyl lactone, 0.0173 g of a fluorine-based leveling agent (F-554, DNP Co., Ltd.) are added thereto, the mixture is agitated, and the resulting mixture is filtered with a 0.45 μm fluoro resin filter, obtaining a positive photosensitive resin composition.

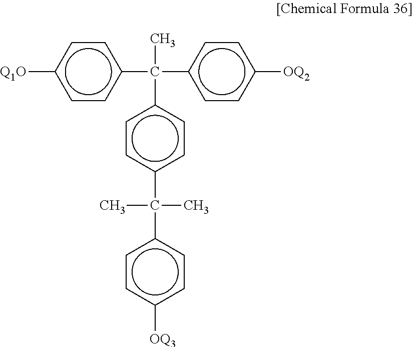

In the above Chemical Formula 36, Q₁ to Q₃ are independently hydrogen atom or

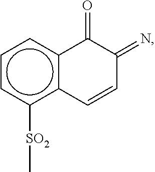

provided both are not hydrogen atoms.

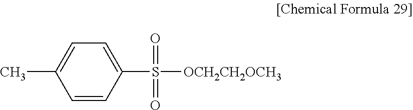

### Examples 12 to 22 and Comparative Examples 11 to 20

A polybenzoxazole precursor (PHA-D2) and a positive photosensitive resin composition are obtained according to the same method as Examples 1 to 11 and Comparative Examples 1 to 10 except for using the polybenzoxazole precursor (PHA-2) of Synthesis Example 2 instead of the polybenzoxazole precursor (PHA-1) of Synthesis Example 1 in Examples 1 to 11 and Comparative Examples 1 to 10.

A solution used to purify the polybenzoxazole precursor has a composition ratio provided in the following Table 1.

TABLE 1
(solvent unit: mL)

| | | | | | | | | Weight | |
|---|---|---|---|---|---|---|---|---|---|
| | | | | | | | | average | |
| | Ultra | | | | | | Polyben- | molecular | Polydis- |
| | pure | | Acetic | | | | zoxazole | weight | persity |
| | water | THF | acid | Acetone | Methanol | IPA | precursor | (Mw) | (PD) |
| Example 1 | 3000 | 2000 | 0 | 0 | 0 | 0 | PHA-D1 | 7350 | 1.45 |
| Example 2 | 3500 | 1500 | 0 | 0 | 0 | 0 | | 7200 | 1.49 |
| Example 3 | 4500 | 500 | 0 | 0 | 0 | 0 | | 7100 | 1.58 |
| Example 4 | 3000 | 0 | 2000 | 0 | 0 | 0 | | 7250 | 1.46 |
| Example 5 | 3500 | 0 | 1500 | 0 | 0 | 0 | | 7200 | 1.51 |
| Example 6 | 4500 | 0 | 500 | 0 | 0 | 0 | | 7100 | 1.56 |
| Example 7 | 3000 | 0 | 0 | 2000 | 0 | 0 | | 7250 | 1.54 |
| Example 8 | 3500 | 0 | 0 | 1500 | 0 | 0 | | 7200 | 1.58 |
| Example 9 | 4500 | 0 | 0 | 500 | 0 | 0 | | 7100 | 1.6 |
| Example 10 | 3500 | 900 | 600 | 0 | 0 | 0 | | 7260 | 1.41 |
| Example 11 | 3500 | 0 | 900 | 600 | 0 | 0 | | 7320 | 1.39 |
| Example 12 | 3000 | 2000 | 0 | 0 | 0 | 0 | PHA-D2 | 8800 | 1.49 |
| Example 13 | 3500 | 1500 | 0 | 0 | 0 | 0 | | 8710 | 1.52 |
| Example 14 | 4500 | 500 | 0 | 0 | 0 | 0 | | 8560 | 1.58 |
| Example 15 | 3000 | 0 | 2000 | 0 | 0 | 0 | | 8860 | 1.51 |
| Example 16 | 3500 | 0 | 1500 | 0 | 0 | 0 | | 8790 | 1.59 |
| Example 17 | 4500 | 0 | 500 | 0 | 0 | 0 | | 8610 | 1.6 |
| Example 18 | 3000 | 0 | 0 | 2000 | 0 | 0 | | 8720 | 1.49 |
| Example 19 | 3500 | 0 | 0 | 1500 | 0 | 0 | | 8670 | 1.52 |
| Example 20 | 4500 | 0 | 0 | 500 | 0 | 0 | | 8520 | 1.6 |
| Example 21 | 3500 | 900 | 600 | 0 | 0 | 0 | | 8930 | 1.55 |
| Example 22 | 3500 | 0 | 900 | 600 | 0 | 0 | | 8810 | 1.49 |
| Comparative | 3000 | 0 | 0 | 0 | 2000 | 0 | PHA-D1 | 7200 | 1.64 |
| Example 1 | | | | | | | | | |
| Comparative | 3500 | 0 | 0 | 0 | 1500 | 0 | | 7150 | 1.67 |
| Example 2 | | | | | | | | | |
| Comparative | 4500 | 0 | 0 | 0 | 500 | 0 | | 7070 | 1.69 |
| Example 3 | | | | | | | | | |
| Comparative | 3000 | 0 | 0 | 0 | 0 | 2000 | | 7160 | 1.65 |
| Example 4 | | | | | | | | | |
| Comparative | 3500 | 0 | 0 | 0 | 0 | 1500 | | 7090 | 1.69 |
| Example 5 | | | | | | | | | |
| Comparative | 4500 | 0 | 0 | 0 | 0 | 500 | | 7010 | 1.73 |
| Example 6 | | | | | | | | | |
| Comparative | 5000 | 0 | 0 | 0 | 0 | 0 | | 7000 | 1.72 |
| Example 7 | | | | | | | | | |
| Comparative | 1400 | 600 | 0 | 0 | 0 | 0 | | 7700 | 1.62 |
| Example 8 | | | | | | | | | |
| Comparative | 1400 | 0 | 600 | 0 | 0 | 0 | | 7620 | 1.65 |
| Example 9 | | | | | | | | | |
| Comparative | 1400 | 0 | 0 | 600 | 0 | 0 | | 7600 | 1.67 |
| Example 10 | | | | | | | | | |
| Comparative | 3000 | 0 | 0 | 0 | 2000 | 0 | PHA-D2 | 8720 | 1.7 |
| Example 11 | | | | | | | | | |
| Comparative | 3500 | 0 | 0 | 0 | 1500 | 0 | | 8650 | 1.74 |
| Example 12 | | | | | | | | | |
| Comparative | 4500 | 0 | 0 | 0 | 500 | 0 | | 8550 | 1.77 |
| Example 13 | | | | | | | | | |
| Comparative | 3000 | 0 | 0 | 0 | 0 | 2000 | | 8690 | 1.78 |
| Example 14 | | | | | | | | | |
| Comparative | 3500 | 0 | 0 | 0 | 0 | 1500 | | 8630 | 1.79 |
| Example 15 | | | | | | | | | |
| Comparative | 4500 | 0 | 0 | 0 | 0 | 500 | | 8510 | 1.81 |
| Example 16 | | | | | | | | | |
| Comparative | 5000 | 0 | 0 | 0 | 0 | 0 | | 8500 | 1.81 |
| Example 17 | | | | | | | | | |
| Comparative | 8400 | 3600 | 0 | 0 | 0 | 0 | | 8610 | 1.68 |
| Example 18 | | | | | | | | | |
| Comparative | 8400 | 0 | 3600 | 0 | 0 | 0 | | 8720 | 1.7 |
| Example 19 | | | | | | | | | |
| Comparative | 8400 | 0 | 0 | 3600 | 0 | 0 | | 8670 | 1.74 |
| Example 20 | | | | | | | | | |

### Formation of Film and Pattern

The positive photosensitive resin compositions according to Example 1 to 22 and Comparative Examples 1 to 20 are respectively coated on an ITO glass with a spin-coater and heated on a hot plate at 130° C. for 2 minutes, forming each film.

### Evaluation

1. Measurement of Molecular Weight

Molecular weight of the polybenzoxazole precursors is measured by diluting 0.02 g of a polybenzoxazole precursor into 0.5 wt % with 4 g of a tetrahydrofuran (THF) solution and setting a calibration curve at Standard A, B. The molecular weight (Mw) measurement of the polybenzoxazole precursors in a GPC method is performed under the following conditions.

Measurement device: detector waters 2414

HPLC pump waters 1515

Autosampler waters 717

Measurement condition: column KF series 803, 802, 801

Solution: THF

Flow rate: 1.0 ml/min

2. Measurement of Film Residue Ratio

The pre-baked film is developed in a 2.38% tetramethylammonium hydroxide (TMAH) aqueous solution at 23° C. for 60 seconds, washed with ultrapure water for 60 seconds, and dried, its thickness change is calculated by using Alpha Step (Tencor Corp.), and then, a film residue ratio is calculated according to the following equation 1.

Film residue ratio (%)=(film thickness after development/initial film thickness before development)×100 [Equation 1]

3. Measurement of Sensitivity

Sensitivity of the films is measured by measuring exposure time to take until a 10 μm L/S pattern is formed to have a line width of 1:1 after the exposure and development and regarding it as optimal exposure time. Resolution of the films is obtained by measuring a minimum pattern size in the optima exposure time.

4. Residue Evaluation (Development Residue Evaluation)

Residue level of the pattern formed by using the photosensitive resin compositions is examined with an optical microscope. The residue is evaluated according to the following reference.

<Residue Evaluation Reference>

o: a development residue (scum) is found

x: no development residue (scum) is found

5. Out-gas Evaluation

Out-gas of the films formed by using and curing the photosensitive resin compositions is measured with TD-GC/MS. The out-gas measurement is performed under the conditions provided in the following Table 2.

(1) Equipment and Apparatus
TD: JTD505
GC/MS: Perkin Elmer Clarus 600
TD tube 150 mm

(2) Measurement Condition

TABLE 2

| | Model | | | | |
|---|---|---|---|---|---|
| | JAI JTD-505 | | | | |
| | | Purge & | | | |
| Method | Air purge | trap | Standby | Desorb | Analysis |

| | | | | | |
|---|---|---|---|---|---|
| TD | 1 min | 20 min | 1 min | 5 min | 35 min |
| | PAT | PAT | PAT | PAT | PAT |
| | 50° C. | 280° C. | 50° C. | 50° C. | 50° C. |
| | SAT | SAT | SAT | SAT | SAT |
| | −40° C. | −40° C. | −40° C. | 280° C. | 280° C. |

| | | |
|---|---|---|
| GC/MS | Column | DB-5MS → 30 m 0.25 mm 0.25 μm |
| | | (5% phenylmethyl polysiloxane) |
| | Mobile | He |
| | phase | |
| | Flow | 1.0 mL/min (Average velocity = 32 cm/s) |
| | Split | Split ratio = 100:1 |
| | Method | 40° C. (3 min) −20° C./min→ 320° C. (6 min) |
| | Detector | MSD |

Sensitivity, film residue ratio, residue, and out-gas of the positive photosensitive resin compositions according to Examples 1 to 22 and Comparative Examples 1 to 20 are evaluated, and the results are provided in the following Table 3.

TABLE 3

| | Poly- | Film residue | | | |
|---|---|---|---|---|---|
| | benzoxazole | ratio | Sensitivity | Scum | Out-gas |
| | precursor | (R.R, %) | (mJ/cm²) | (∘/x) | (ng/cm²) |
| Example 1 | PHA-D1 | 82 | 175 | x | 3 |
| Example 2 | | 80 | 171 | x | 4 |
| Example 3 | | 78 | 162 | x | 6 |
| Example 4 | | 81 | 181 | x | 4 |
| Example 5 | | 80 | 174 | x | 5 |
| Example 6 | | 78 | 165 | x | 7 |
| Example 7 | | 81 | 179 | x | 4 |
| Example 8 | | 82 | 168 | x | 4 |
| Example 9 | | 80 | 152 | x | 5 |
| Example 10 | | 78 | 166 | x | 0 |
| Example 11 | | 81 | 171 | x | 0 |
| Example 12 | PHA-D2 | 90 | 205 | x | 2 |
| Example 13 | | 88 | 194 | x | 2 |
| Example 14 | | 85 | 176 | x | 3 |
| Example 15 | | 88 | 192 | x | 1 |
| Example 16 | | 88 | 184 | x | 2 |
| Example 17 | | 86 | 174 | x | 4 |
| Example 18 | | 88 | 200 | x | 2 |
| Example 19 | | 88 | 195 | x | 2 |
| Example 20 | | 86 | 180 | x | 4 |
| Example 21 | | 91 | 185 | x | 0 |
| Example 22 | | 90 | 180 | x | 0 |
| Comparative | PHA-D1 | 80 | 230 | x | 98 |
| Example 1 | | | | | |
| Comparative | | 80 | 210 | x | 115 |
| Example 2 | | | | | |
| Comparative | | 75 | 176 | ∘ | 140 |
| Example 3 | | | | | |
| Comparative | | 76 | 225 | x | 130 |
| Example 4 | | | | | |
| Comparative | | 75 | 200 | ∘ | 142 |
| Example 5 | | | | | |
| Comparative | | 74 | 170 | ∘ | 155 |
| Example 6 | | | | | |
| Comparative | | 72 | 199 | ∘ | 376 |
| Example 7 | | | | | |
| Comparative | | 85 | 186 | x | 10 |
| Example 8 | | | | | |
| Comparative | | 84 | 172 | x | 12 |
| Example 9 | | | | | |
| Comparative | | 83 | 191 | x | 12 |
| Example 10 | | | | | |
| Comparative | PHA-D2 | 88 | 172 | x | 130 |
| Example 11 | | | | | |
| Comparative | | 88 | 191 | x | 155 |
| Example 12 | | | | | |
| Comparative | | 88 | 186 | ∘ | 162 |
| Example 13 | | | | | |
| Comparative | | 86 | 172 | x | 141 |
| Example 14 | | | | | |
| Comparative | | 91 | 172 | ∘ | 146 |
| Example 15 | | | | | |
| Comparative | | 90 | 191 | ∘ | 139 |
| Example 16 | | | | | |
| Comparative | | 88 | 186 | ∘ | 420 |
| Example 17 | | | | | |
| Comparative | | 88 | 186 | x | 30 |
| Example 18 | | | | | |
| Comparative | | 86 | 172 | x | 26 |
| Example 19 | | | | | |
| Comparative | | 88 | 191 | x | 33 |
| Example 20 | | | | | |

As shown in Table 3, the positive photosensitive resin compositions according to Examples 1 to 22 have a polydispersity of 1 to 1.6 since a low molecular component is removed in a polybenzoxazole precursor and thus, exhibit excellent sensitivity and film residue ratio, no residue, and very small out-gas compared with the positive photosensitive resin compositions having polydispersity of greater than 1.6 according to Comparative Examples 1 to 20.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

What is claimed is:

1. A positive photosensitive resin composition, comprising:
(A) a polybenzoxazole precursor having a polydispersity of about 1 to about 1.6;
(B) a photosensitive diazoquinone compound;
(C) a thermal acid generator; and
(D) a solvent.

2. The photosensitive resin composition of claim 1, wherein the polybenzoxazole precursor has a weight average molecular weight (Mw) of about 3,000 g/mol to about 30,000 g/mol.

3. The photosensitive resin composition of claim 1, wherein the polybenzoxazole precursor comprises a repeating unit represented by the following Chemical Formula 1: 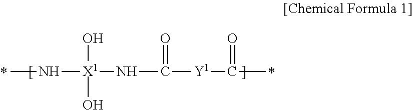
wherein, in the above Chemical Formula 1,
each X¹ is the same or different and each is independently a substituted or unsubstituted C6 to C30 aromatic organic group, and
each Y¹ is the same or different and each is independently a substituted or unsubstituted C6 to C30 aromatic organic group, a substituted or unsubstituted divalent to hexavalent C1 to C30 aliphatic organic group, or a substituted or unsubstituted divalent to hexavalent C3 to C30 alicyclic organic group.

4. The photosensitive resin composition of claim 1, wherein the positive photosensitive resin composition comprises:
about 5 parts by weight to about 100 parts by weight of the photosensitive diazoquinone compound (B);
about 1 part by weight to about 50 parts by weight of the thermal acid generator (C); and
about 100 parts by weight to about 400 parts by weight of the solvent (D)
each based on about 100 parts by weight of the polybenzoxazole precursor (A).

5. The photosensitive resin composition of claim 1, wherein the positive photosensitive resin composition further comprises an additive including a silane compound, a surfactant, a leveling agent, or a combination thereof.

6. A photosensitive resin film prepared using the positive photosensitive resin composition of claim 1.

7. A display device including the photosensitive resin film of claim 6.
